(19) United States
(12) Patent Application Publication
(10) Pub. No.: US 2023/0411357 A1
(43) Pub. Date: Dec. 21, 2023

(54) SEMICONDUCTOR DEVICE AND SEMICONDUCTOR DEVICE MANUFACTURING METHOD

(71) Applicant: Kioxia Corporation, Tokyo (JP)

(72) Inventor: Jun TANAKA, Kuwana Mie (JP)

(73) Assignee: Kioxia Corporation, Tokyo (JP)

(21) Appl. No.: 18/335,334

(22) Filed: Jun. 15, 2023

(30) Foreign Application Priority Data
Jun. 17, 2022 (JP) 2022-097918

(51) Int. Cl. H01L 25/065; H01L 23/31; H01L 23/00; H01L 23/16; H10B 80/00

(52) U.S. Cl. CPC H01L 25/0657; H01L 23/3107; H01L 24/48; H01L 23/16; H10B 80/00; H01L 2225/06562; H01L 2225/0651; H01L 2225/06506; H01L 2224/48225; H01L 2224/48145; H01L 2224/32225; H01L 24/32; H01L 2224/32145; H01L 2224/73215; H01L 24/73; H01L 2224/33181; H01L 24/33; H01L 2224/49112; H01L 24/49

(57) ABSTRACT

A semiconductor device includes a first chip stacked body including a plurality of first semiconductor chips stacked in a stacking direction, the first chip stacked body having a first surface and a second surface at respective ends on a first side and a second side in the stacking direction; a spacer extending in the stacking direction and positioned with respect to the first chip stacked body in a direction intersecting the stacking direction, the spacer having a third surface and a fourth surface at the respective ends on the first side and the second side in the stacking direction; a second semiconductor chip and a first resin layer provided across the second surface of the first chip stacked body and the fourth surface of the spacer, the first resin layer being positioned between the second semiconductor chip and each of the spacer and the first chip stacked body; and a second resin layer provided on the third surface of the spacer and having a thickness larger than a thickness of the first resin layer.

### CROSS-REFERENCE TO RELATED APPLICATION

This application is based upon and claims the benefit of priority from Japanese Patent Application No. 2022-97918, filed on Jun. 17, 2022, the entire contents of which are incorporated herein by reference.

### BACKGROUND OF THE INVENTION

### Field of the Invention

The present embodiment relates to a semiconductor device and a semiconductor device manufacturing method.

### Description of the Related Art

Some semiconductor devices each contain a plurality of stacked chips. The stacked chips are fixed to each other by a resin layer provided between the chips.

### BRIEF DESCRIPTION OF THE DRAWINGS

FIG. 1 is a sectional schematic diagram of a semiconductor device of the present embodiment;

FIG. 2A is a schematic diagram illustrating a process of manufacturing the semiconductor device of the present embodiment;

FIG. 2B is a schematic diagram illustrating the process of manufacturing the semiconductor device of the present embodiment;

FIG. 2C is a schematic diagram illustrating the process of manufacturing the semiconductor device of the present embodiment;

FIG. 2D is a schematic diagram illustrating the process of manufacturing the semiconductor device of the present embodiment;

FIG. 3 is a characteristic diagram of temperature change of the elastic modulus of die attach films;

FIG. 4A is a schematic diagram illustrating the process of manufacturing the semiconductor device of the present embodiment;

FIG. 4B is a schematic diagram illustrating the process of manufacturing the semiconductor device of the present embodiment;

FIG. 4C is a schematic diagram illustrating the process of manufacturing the semiconductor device of the present embodiment;

FIG. 4D is a schematic diagram illustrating the process of manufacturing the semiconductor device of the present embodiment;

FIG. 4E is a schematic diagram illustrating the process of manufacturing the semiconductor device of the present embodiment;

FIG. 4F is a schematic diagram illustrating the process of manufacturing the semiconductor device of the present embodiment;

FIG. 4G is a schematic diagram illustrating the process of manufacturing the semiconductor device of the present embodiment;

FIG. 4H is a schematic diagram illustrating the process of manufacturing the semiconductor device of the present embodiment;

FIG. 5C is a schematic diagram illustrating a process of manufacturing a semiconductor device according to a comparative example; and

FIG. 5D is a schematic diagram illustrating the process of manufacturing the semiconductor device according to the comparative example.

### DETAILED DESCRIPTION OF THE PREFERRED EMBODIMENTS

The present embodiment will be described below with reference to the accompanying drawings. To facilitate understanding of description, any identical components in the drawings are denoted by the same reference sign as much as possible, and duplicate description thereof is omitted.

The configuration of a semiconductor device 10 according to the present embodiment will be described below. An x axis, a y axis, and a z axis are illustrated in some drawings. The x axis, the y axis, and the z axis constitute a right-handed three-dimensional orthogonal coordinate system. Hereinafter, the direction of an arrow along the x axis is also referred to as a positive x-axis side and the direction opposite the arrow is also referred to as a negative x-axis side, and this is the same for the other axes. The positive z-axis side (second side) and the negative z-axis side (first side) are also referred to as a “controller side” and a “support substrate side”, respectively. The negative x-axis side is also referred to as a “spacer side”. The z axial direction is also referred to as a “stacking direction”. Planes orthogonal to the x axis, the y axis, and the z axis are referred to as a yz plane, a zx plane, and an xy plane, respectively.

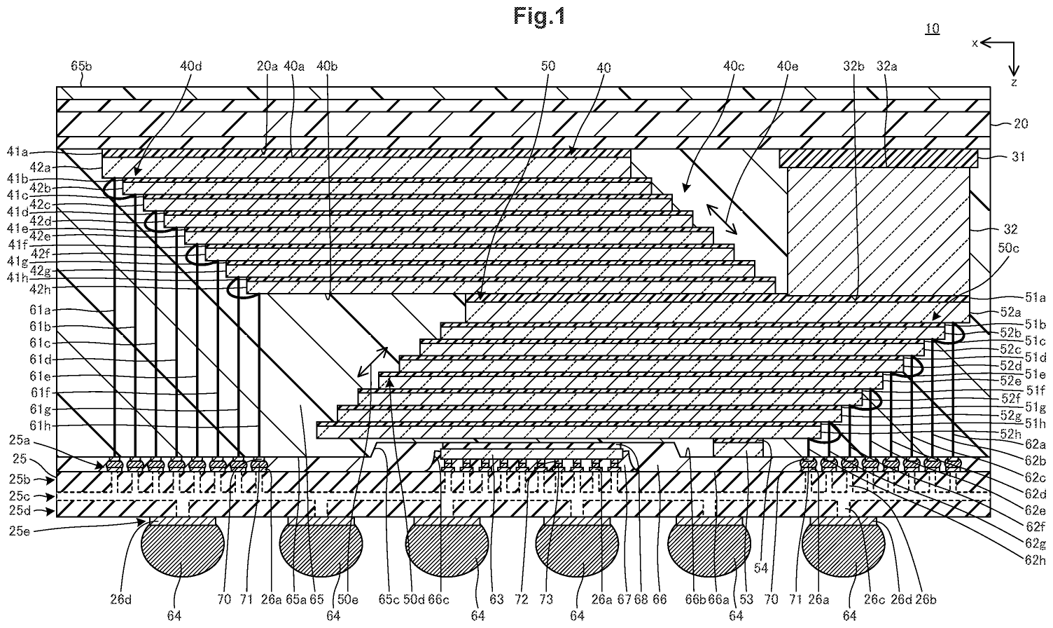

FIG. 1 illustrates the semiconductor device 10 in a completed state. As illustrated in FIG. 1, the semiconductor device 10 includes a support substrate 20, a wiring substrate 25, a die attach film 31 (second resin layer), a spacer 32, die attach films 41a to 41h, semiconductor chips 42a to 42h, die attach films 51a to 51h, semiconductor chips 52a to 52h, vertical wires 61a to 61h and 62a to 62h, and sealing portions 65, 66, and 67.

The semiconductor chip 52a is an example of a “second semiconductor chip” of the present embodiment. Each of the semiconductor chips 52b to 52h is an example of a “third semiconductor chip” of the present embodiment. The die attach film 51a is an example of a “first resin layer” of the present embodiment. The die attach film 41a is an example of a “third resin layer” of the present embodiment.

Hereinafter, each of the die attach films 41a to 41h is also referred to as a die attach film 41. Each of the semiconductor chips 42a to 42h is also referred to as a semiconductor chip 42 (first semiconductor chip). Each of the die attach films 51a to 51h is also referred to as a die attach film 51. Each of the semiconductor chips 52a to 52h is also referred to as a semiconductor chip 52. Each of the vertical wires 61a to 61h is also referred to as a vertical wire 61. Each of the vertical wires 62a to 62h is also referred to as a vertical wire 62.

A chip stacked body 40 (first chip stacked body) includes the die attach films 41b to 41h and the eight semiconductor chips 42a to 42h stacked in the stacking direction. A chip stacked body 50 (second chip stacked body) includes the die attach films 51b to 51h and the eight semiconductor chips 52a to 52h stacked in the stacking direction.

The semiconductor chips 42 and 52 are memory chips capable of storing, for example, data. Specifically, the semiconductor chips 42 and 52 are NAND flash memory chips. At least one of the semiconductor chips 42 and 52 may be a DRAM chip or a chip having another function. The shapes of the semiconductor chips 42 and 52 are plate shapes having surfaces substantially parallel to the xy plane on the controller side and the support substrate side.

The support substrate 20 is a plate member having a rectangular surface (hereinafter, also referred to as a principal surface 20a) that is substantially parallel to the xy plane and positioned on the controller side. In the present embodiment, the support substrate 20 is a substrate in which solder resist layers are provided on the positive z-axis side and the negative z-axis side of an insulating layer, respectively.

The die attach films 41b to 41h, 51b to 51h, and 31 are made of heat-curable resin as a bonding agent that fixes components when heated. In the present embodiment, the die attach films 41b to 41h, 51b to 51h, and 31 are used to fix the semiconductor chips 42 and 52 and the spacer 32 to the support substrate 20.

The semiconductor chip 42a is fixed to the principal surface 20a of the support substrate 20 by the die attach film 41a. The thickness of the semiconductor chip 42a in the stacking direction is larger than those of the other semiconductor chips 42b to 42h. This can reduce influence of irregularities of the principal surface 20a of the support substrate 20 on the semiconductor chips 42b to 42h.

The semiconductor chips 42b, 42c, 42d, 42e, 42f, 42g, and 42h are stacked on the controller side of the semiconductor chip 42a in the stated order from the support substrate side toward the controller side.

The semiconductor chips 42b, 42c, 42d, 42e, 42f, 42g, and 42h are fixed to a semiconductor chip 42 on the support substrate side by the die attach films 41b, 41c, 41d, 41e, 41f, 41g, and 41h, respectively.

Accordingly, the chip stacked body 40 is fixed to the principal surface 20a of the support substrate 20 by the die attach film 41a. The chip stacked body 40 has a surface 40a (first surface) and a surface 40b (second surface) at respective ends on the support substrate side and the controller side in the stacking direction. The chip stacked body 40 is positioned near the center of the principal surface 20a in a plan view in which the principal surface 20a is viewed in the stacking direction.

In the chip stacked body 40, the eight semiconductor chips 42 are stacked such that stair portions 40c (first stair portion) and 40d (second stair portion) are formed at a side surface facing the spacer 32 and at a side surface on a side further apart from the spacer 32, respectively.

The stair portion 40c is formed at the side surface of the chip stacked body 40 on the negative x-axis side and has a stair shape in which the stair portion 40c is further apart from the spacer 32 at a position further apart from the semiconductor chip 52a, in other words, a stair shape in which the stair portion 40c is closer to the spacer 32 on the controller side than on the support substrate side.

The stair portion 40d is formed at the side surface of the chip stacked body 40 on the positive x-axis side and has a stair shape similar to the stair shape of the stair portion 40c. A stair up-down direction 40e (first stair up-down direction) of the stair portions 40c and 40d is the direction of a line connecting northwest and southeast when the zx plane is viewed such that directions toward the positive z-axis side and the positive x-axis side align with the directions of north and east, respectively.

In the present embodiment, the shapes of the semiconductor chips 42 in a plan view in which the surface 40b is viewed in the stacking direction are rectangles each having two facing sides substantially parallel to the x axis and two facing sides substantially parallel to the y axis and having substantially same sizes.

Each semiconductor chip 42 on the controller side is shifted on the negative x-axis side from a semiconductor chip 42 on the support substrate side and fixed to the semiconductor chip 42 on the support substrate side. Accordingly, the stair portions 40c and 40d with eight stairs are formed on the side surfaces of the chip stacked body 40 on the negative x-axis side and the positive x-axis side, respectively.

In the above-described configuration, the thickness of the semiconductor chip 42a in the stacking direction is larger than those of the other semiconductor chips 42b to 42h, but the present invention is not limited to the configuration. The thickness of the semiconductor chip 42a in the stacking direction may be substantially equal to the thickness of each of the other semiconductor chips 42b to 42h in the stacking direction.

The spacer 32 is positioned with respect to the chip stacked body 40 in a direction intersecting the stacking direction. In the present embodiment, the spacer 32 is positioned on the negative x-axis side of the chip stacked body 40.

The spacer 32 is a pillar-shaped spacer extending in the stacking direction. The spacer 32 is formed of, for example, a semiconductor. The spacer 32 has a surface 32a (third surface) and a surface 32b (fourth surface) at ends on the negative z-axis side and the positive z-axis side in the stacking direction, respectively.

The die attach film 31 is provided between the surface 32a of the spacer 32 and the principal surface 20a of the support substrate 20. In the present embodiment, the die attach film 31 contacts the principal surface 20a and the surface 32a and fixes the spacer 32 to the support substrate 20.

The die attach film 51a and the semiconductor chip 52a are provided across the surface 40b of the chip stacked body 40 and the surface 32b of the spacer 32. The die attach film 51a is positioned between the semiconductor chip 52a and each of the spacer 32 and the chip stacked body 40.

In the present embodiment, the semiconductor chip 52a is fixed across the surface 32b of the spacer 32 and the surface 40b of the chip stacked body 40 by the die attach film 51a. The thickness of the semiconductor chip 52a in the stacking direction is larger than those of the other semiconductor chips 52b to 52h.

The semiconductor chips 52b, 52c, 52d, 52e, 52f, 52g, and 52h are stacked on the controller side of the semiconductor chip 52a in the stated order from the support substrate side toward the controller side.

The semiconductor chips 52b, 52c, 52d, 52e, 52f, 52g, and 52h are fixed to a semiconductor chip 52 on the support substrate side by the die attach films 51b, 51c, 51d, 51e, 51f, 51g, and 51h, respectively.

Accordingly, the chip stacked body 50 is fixed across the surface 32b of the spacer 32 and the surface 40b of the chip stacked body 40 by the die attach film 51a. The chip stacked body 50 is positioned near the center of the principal surface 20a in a plan view in which the principal surface 20a is viewed in the stacking direction.

In the chip stacked body 50, the eight semiconductor chips 52 are stacked such that stair portions 50c (third stair portion) and 50d (third stair portion) are formed at a side surface on the negative x-axis side and at a side surface on the positive x-axis side, respectively.

The stair portion 50c is formed at the side surface of the chip stacked body 50 on the negative x-axis side and has a stair shape in a stair up-down direction 50e (second stair up-down direction) intersecting the stair up-down direction 40e of the stair portion 40c. The stair portion 50d is formed at the side surface of the chip stacked body 50 on the positive x-axis side and has a stair shape similar to the stair shape of the stair portion 50c.

The stair up-down direction 50e of the stair portions 50c and 50d is the direction of a line connecting northeast and southwest when the zx plane is viewed such that directions toward the positive z-axis side and the positive x-axis side align with the directions of north and east, respectively.

In the present embodiment, the shapes of the semiconductor chips 52 in a plan view in which the surface 40b is viewed in the stacking direction are rectangles each having two facing sides substantially parallel to the x axis and two facing sides substantially parallel to the y axis and having substantially same sizes.

Each semiconductor chip 52 on the controller side is shifted on the positive x-axis side from a semiconductor chip 52 on the support substrate side and fixed to the semiconductor chip 52 on the support substrate side. Accordingly, the stair portions 50c and 50d with eight stairs are formed on the side surfaces of the chip stacked body 50 on the negative x-axis side and the positive x-axis side, respectively.

In the above-described configuration, the thickness of the semiconductor chip 52a in the stacking direction is larger than those of the other semiconductor chips 52b to 52h, but the present invention is not limited to the configuration. The thickness of the semiconductor chip 52a in the stacking direction may be substantially equal to the thickness of each of the other semiconductor chips 52b to 52h in the stacking direction.

The sealing portion 65 seals the support substrate 20, the spacer 32, the die attach films 31, 41, and 51, the semiconductor chips 42 and 52, and the vertical wires 61 and 62. The sealing portion 65 is formed of a thermoplastic insulator such as molding resin. The sealing portion 65 has a surface 65a on the controller side and a surface 65b on the support substrate side. A recessed portion 65c that is recessed on the support substrate side is formed at the surface 65a. The recessed portion 65c is positioned near the center of the principal surface 20a in a plan view in which the principal surface 20a is viewed in the stacking direction.

In a plan view in which the surface 40b is viewed in the stacking direction, the semiconductor chip 52a, the die attach film 51a, and the stair portion 40d are apart from one another. In the present embodiment, the chip stacked body 50 and the stair portion 40d are apart from each other in this plan view. The eight vertical wires 61 extend toward the controller side from the eight respective surfaces of the stair portion 40d on the controller side.

Specifically, the vertical wires 61a to 61h extend substantially in parallel to the stacking direction from surfaces of the respective semiconductor chips 42a to 42h to the surface 65a through the sealing portion 65, the surfaces being positioned on the controller side and close to end parts on the positive x-axis side.

Since the vertical wires 61a to 61h are vertically positioned in this manner, the disposition pitch between the vertical wires 61a to 61h can be easily reduced.

The eight vertical wires 62 extend toward the controller side from the eight respective surfaces of the stair portion 50c on the controller side. Specifically, the vertical wires 62a to 62h extend substantially in parallel to the stacking direction from surfaces of the respective semiconductor chips 52a to 52h to the surface 65a through the sealing portion 65, the surfaces being positioned on the controller side and close to end parts on the negative x-axis side.

Since the vertical wires 62a to 62h are vertically positioned in this manner, the disposition pitch between the vertical wires 62a to 62h can be easily reduced.

The vertical wires 61 and 62 are formed of a conductive material containing metal (for example, gold) as a primary component. End parts of the vertical wires 61 and 62 on the controller side are each connected to a wiring pattern 26a on the wiring substrate 25 through an electrode 70 and a bump 71.

A semiconductor chip 63 has a function different from that of the semiconductor chips 42 and 52 and is a controller chip capable of controlling, for example, the semiconductor chips 42a to 42h and 52a to 52h.

The semiconductor chip 63 is electrically connected to the semiconductor chips 42a to 42h and 52a to 52h. To uniform wiring lengths to the semiconductor chips 42a to 42h and 52a to 52h, the semiconductor chip 63 is preferably provided near the center of the principal surface 20a in a plan view in which the principal surface 20a is viewed in the stacking direction. Thus, the semiconductor chip 63 is connected to the bottom of the recessed portion 65c of the sealing portion 65 through a resin portion 68. The resin portion 68 is cured adhesive resin and bonds the semiconductor chip 63 to the bottom of the recessed portion 65c.

A plurality of electrodes 72 are provided on a surface of the semiconductor chip 63 on the positive z-axis side. The plurality of electrodes 72 are connected to the wiring patterns 26a on the wiring substrate 25 through bumps 73.

A spacer 53 is used for end point detection when the vertical wires 61 and 62 are exposed by deleting the sealing portion 65.

The sealing portion 66 fills the recessed portion 65c of the sealing portion 65 and seals the electrodes 70, the bumps 71, and the wiring patterns 26a connected to the bumps 71. The sealing portion 66 has a surface 66a on the controller side and a surface 66b on the support substrate side, the surface 66a contacting the wiring substrate 25, the surface 66b contacting the surface 65a of the sealing portion 65.

The sealing portion 67 seals the semiconductor chip 63, the electrodes 72, the bumps 73, and the wiring patterns 26a connected to the bumps 73.

The wiring substrate 25 includes conductive layers 25a, 25c, and 25e and insulating layers 25b and 25d. The conductive layer 25a, the insulating layer 25b, the conductive layer 25c, the insulating layer 25d, and the conductive layer 25e extend in substantially parallel to the xy plane and are stacked in the stated order from the support substrate side toward the controller side.

The conductive layer 25a includes the wiring patterns 26a, and the conductive layer 25e includes wiring patterns 26d. The insulating layers 25b and 25d are formed of, for example, prepreg. A plurality of through-hole electrodes 26b penetrating in the stacking direction are formed in the insulating layer 25b. The through-hole electrodes 26b electrically connect some electrodes included in the wiring patterns 26a to some electrodes included in the conductive layer 25c.

A plurality of through-hole electrodes 26c penetrating in the stacking direction are formed in the insulating layer 25d. The through-hole electrodes 26c electrically connect some electrodes included in the wiring patterns 26d to some electrodes included in the conductive layer 25c.

A plurality of solder balls 64 are provided on a surface of the wiring substrate 25 on the positive z-axis side and connected to the respective wiring patterns 26d. The disposition pitch between the solder balls 64 in the x axial direction is larger than the disposition pitch between the vertical wires 61 in the x axial direction, the disposition pitch between the vertical wires 62 in the x axial direction, and the disposition pitch between the electrodes 72 on the semiconductor chip 63 in the x axial direction. This is the same for the y axis.

Accordingly, the semiconductor device 10 can be easily connected to external terminals (for example, terminals on a motherboard) having a large pitch although the disposition pitch between the vertical wires 61, the disposition pitch between the vertical wires 62, and the disposition pitch between the electrodes 72 are small.

[Semiconductor Device Manufacturing Method]

A method of manufacturing the semiconductor device 10 will be described below as an exemplary semiconductor device manufacturing method according to the present embodiment.

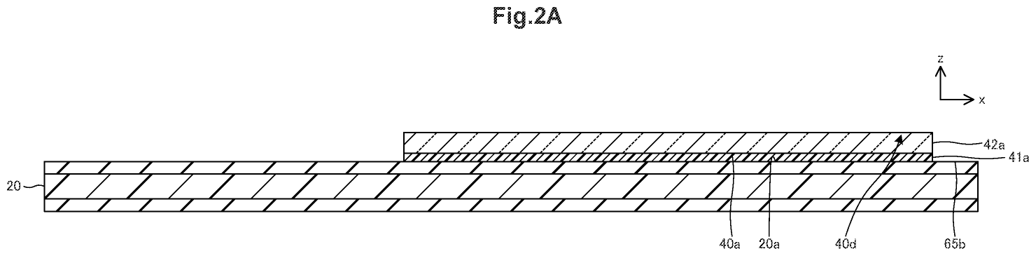

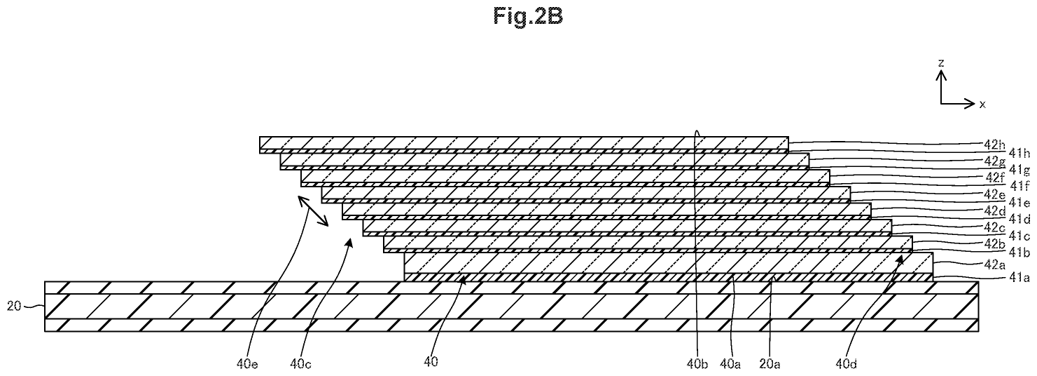

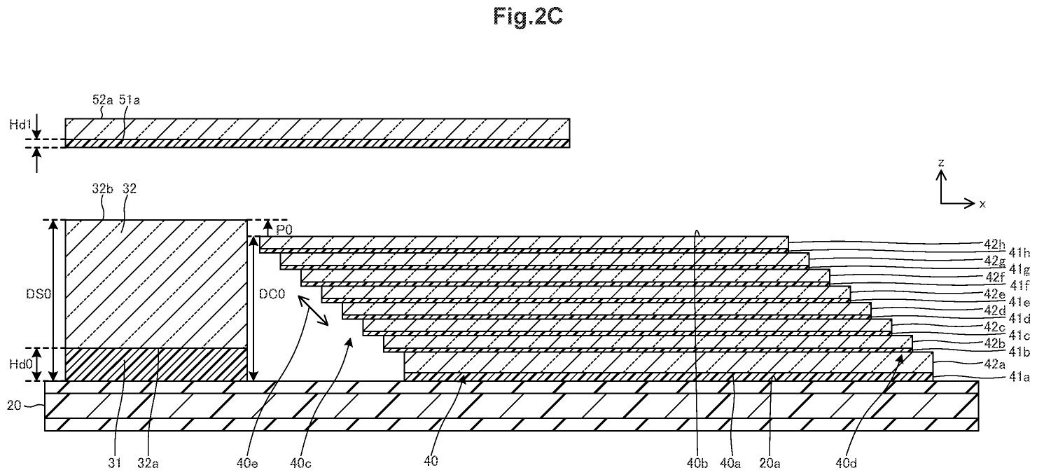

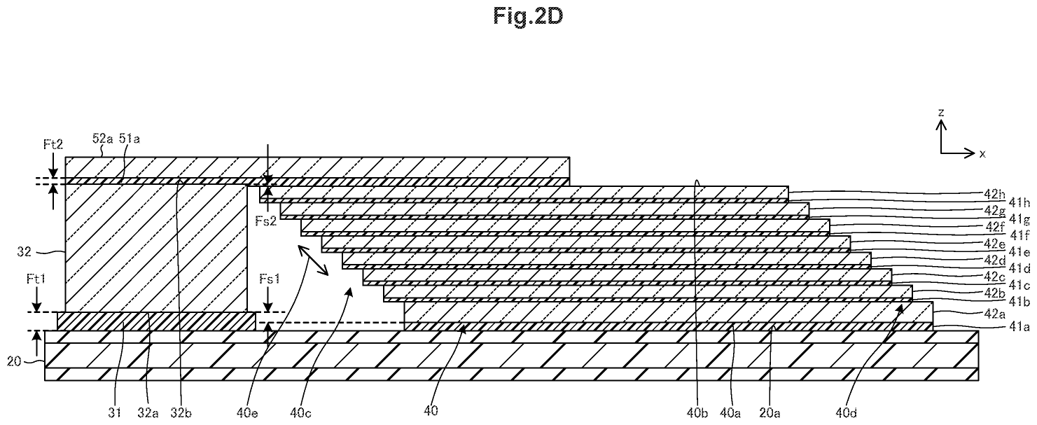

FIGS. 2A to 2D are schematic diagrams illustrating a process of manufacturing the semiconductor device 10. First, the chip stacked body 40 and the die attach film 41a, which is provided between the surface 40a of the chip stacked body 40 and the principal surface 20a of the support substrate 20, are formed on the principal surface 20a.

In the present embodiment, the eight semiconductor chips 42 are stacked on the controller side of the principal surface 20a by disposing and fixing the semiconductor chips 42 one by one with each die attach film 41 interposed therebetween. Alternatively, a stack of a plurality of semiconductor chips 42 may be produced in advance and may be disposed and fixed on the principal surface 20a.

More specifically, as illustrated in FIG. 2A, the semiconductor chip 42a is disposed on the controller side of the principal surface 20a of the support substrate 20 with the die attach film 41a interposed therebetween.

Subsequently, as illustrated in FIG. 2B, the semiconductor chip 42b is disposed on a surface of the semiconductor chip 42a on the controller side with the die attach film 41b interposed therebetween.

Subsequently, similarly, each of the semiconductor chips 42c to 42h on the controller side is fixed to a semiconductor chip 42 on the support substrate side with the corresponding die attach film 41 interposed therebetween. Accordingly, the chip stacked body 40 and the die attach film 41a are formed on the principal surface 20a.

Subsequently, as illustrated in FIG. 2C, the spacer 32 is disposed at a position on the principal surface 20a with the die attach film 31 interposed therebetween, the position being apart on the negative x-axis side from the chip stacked body 40.

In this state, the die attach film 31 has such an initial thickness Hd0 in the stacking direction that a distance DSO between the principal surface 20a and the surface 32b is longer than a distance DC0 between the principal surface 20a and the surface 40b.

More specifically, the initial thickness Hd0 is larger than the sum of the upper limit value of tolerance of the chip stacked body 40, the upper limit value of tolerance of the die attach film 41a, the lower limit value of tolerance of the spacer 32, and the lower limit value of tolerance of the die attach film 31.

Specifically, for example, when tolerance of the thickness of the die attach films 41 and 31 in the stacking direction is ±Td and tolerance of the thickness of the semiconductor chips 42 and the spacer 32 in the stacking direction is ±Tc, the upper limit value of tolerance of the chip stacked body 40 is 7×Td+8×Tc. The upper limit value of tolerance of the die attach film 41a is Td. The lower limit value of tolerance of the spacer 32 is Tc. The lower limit value of tolerance of the die attach film 31 is Td.

Accordingly, the initial thickness Hd0 is larger than 7×Td+8×Tc+Td+Tc+Td=9×(Td+Tc). In other words, a protrusion amount P0 by which the surface 32b of the spacer 32 protrudes on the controller side from the surface 40b of the chip stacked body 40 is larger than zero in a case (hereinafter, also referred to as a tolerance satisfied case) in which the die attach films 41, the semiconductor chips 42, the die attach film 31, and the spacer 32 have thicknesses within tolerance in the stacking direction.

In the present embodiment, the initial thickness Hd0 is 9×(Td+Tc)+α. The value of a is larger than the sum of an initial thickness Hd1 of the die attach film 51a in the stacking direction and the upper limit value of tolerance of the thickness of the die attach film 51a in the stacking direction.

The protrusion amount P0 is maximum in the tolerance satisfied case (hereinafter, this state is also referred to as a maximum protrusion state) when the die attach films 41 and the semiconductor chips 42 have thicknesses at the lower limits of tolerance in the stacking direction and the die attach film 31 and the spacer 32 have thicknesses at the upper limits of tolerance in the stacking direction.

In other words, in the tolerance satisfied case, the maximum protrusion state is reached when the surface 40b of the chip stacked body 40 is closest to the principal surface 20a and the surface 32b of the spacer 32 is farthest from the principal surface 20a.

The protrusion amount P0 is minimum in the tolerance satisfied case (hereinafter, this state is also referred to as a minimum protrusion state) when the die attach films 41 and the semiconductor chips 42 have thicknesses at the upper limits of tolerance in the stacking direction and the die attach film 31 and the spacer 32 have thicknesses at the lower limits of tolerance in the stacking direction.

In other words, in the tolerance satisfied case, the minimum protrusion state is reached when the surface 40b of the chip stacked body 40 is farthest from the principal surface 20a and the surface 32b of the spacer 32 is closest to the principal surface 20a.

Subsequently, at least the die attach film 31 is heated to a predetermined temperature.

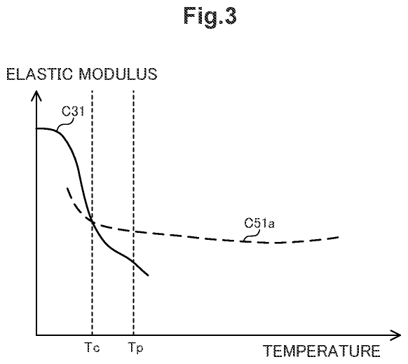

FIG. 3 is a diagram illustrating exemplary temperature change of the elastic modulus of each of the die attach film 31 and the die attach film 51a. In FIG. 3, the horizontal axis represents temperature and the vertical axis represents the elastic modulus.

As illustrated in FIG. 3, a curve C31 and a curve C51a represent temperature change of the elastic moduli of the die attach films 31 and 51a, respectively, before curing by heating. The die attach films 31 and 51a have a temperature beyond which the elastic modulus of the die attach film 31 becomes smaller than the elastic modulus of the die attach film 51a.

The elastic modulus of the die attach film 31 is smaller than the elastic modulus of the die attach film 51a at a certain temperature or higher. Moreover, the elastic modulus of the die attach film 31 when the surface 32a of the spacer 32 is displaced closer to the principal surface 20a is smaller than the elastic modulus of the die attach film 51a.

In the present embodiment, the elastic modulus of the die attach film 31 is smaller than the elastic modulus of the die attach film 51a at a temperature higher than a temperature Tc. The temperature Tc is, for example, 50° C.

At least the die attach film 31 is heated to a temperature Tp higher than the temperature Tc. Alternatively, at least the die attach film 31 is heated to a temperature between the temperature Tc and the temperature Tp. The temperature Tp is, for example, 100° C. The elastic modulus of the die attach film 31 is equal to or smaller than 1 MPa at the temperature Tp. The elastic modulus of the die attach film 51a is larger than 1 MPa at the temperature Tp.

Subsequently, as illustrated in FIG. 2D, the die attach film 51a and the semiconductor chip 52a are disposed across the surface 40b of the chip stacked body 40 and the surface 32b of the spacer 32 such that the die attach film 51a is positioned between the semiconductor chip 52a and each of the spacer 32 and the chip stacked body 40. The surface 32a of the spacer 32 is displaced closer to the principal surface 20a of the support substrate 20 when the die attach film 51a and the semiconductor chip 52a are to be disposed.

In the present embodiment, the semiconductor chip 52a is pressed toward the support substrate side when the die attach film 31 is at the temperature Tp. The die attach film 51a deforms when pressed toward the support substrate side by the semiconductor chip 52a. The die attach film 31 deforms when pressed toward the support substrate side by the semiconductor chip 52a through the spacer 32 and the die attach film 51a. In this state, the surface 32a is displaced closer to the principal surface 20a.

The amount of deformation of the die attach film 31 is larger than the amount of deformation of the die attach film 51a since the die attach film 31 is softer than the die attach film 51a in this state. A thickness Ft1 of the die attach film 31 in the stacking direction becomes smaller than the initial thickness Hd0. The die attach film 31 deforms by circumferentially protruding. An interval Fs1 between the surface 40a and the surface 32a in the stacking direction is larger than an interval Fs2 between the surface 40b and the surface 32b in the stacking direction.

The interval Fs2 is small since the amount of deformation of the die attach film 51a when the semiconductor chip 52a is pressed toward the support substrate side is small.

The amount of displacement of the spacer 32 toward the support substrate side when the semiconductor chip 52a is pressed toward the support substrate side is close to the protrusion amount P0 (refer to FIG. 2C). The thickness Ft1 of the die attach film 31 in the stacking direction decreases by a distance by which the spacer 32 is displaced. Accordingly, the thickness Ft1 of the die attach film 31 in the stacking direction is close to a thickness obtained by subtracting the protrusion amount P0 from the initial thickness Hd0.

For example, the thickness Ft1 is smallest in the tolerance satisfied case when the semiconductor chip 52a is pressed toward the support substrate side in the maximum protrusion state.

The thickness Ft1 is largest in the tolerance satisfied case when the semiconductor chip 52a is pressed toward the support substrate side in the minimum protrusion state.

Thus, the thickness Ft1 reflects variance in the thicknesses of the die attach films 41 and 31, the semiconductor chips 42, and the spacer 32 in the stacking direction.

Since the initial thickness Hd0 is 9×(Td+Tc)+α as described above, the thickness Ft1 is larger than a thickness Ft2 of the die attach film 51a in the stacking direction even when the thickness Ft1 is smallest in the tolerance satisfied case.

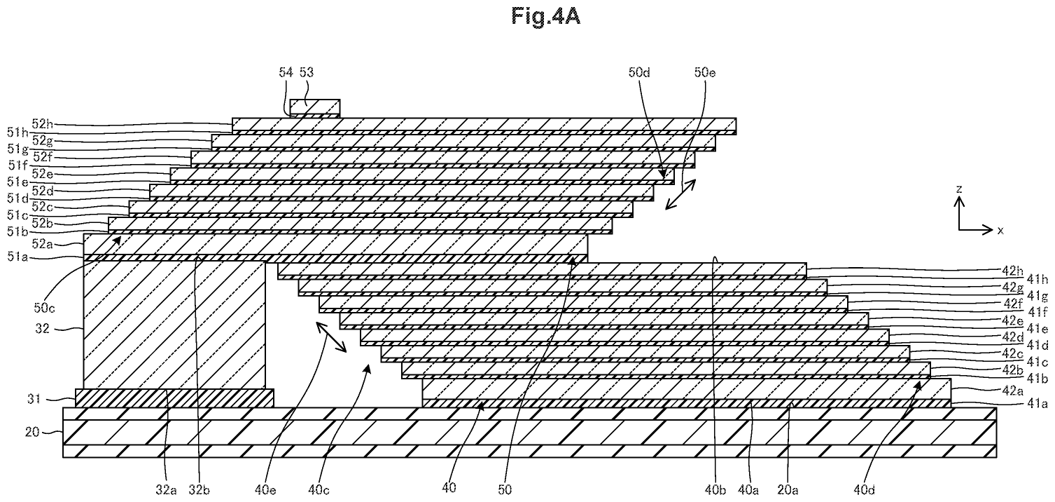

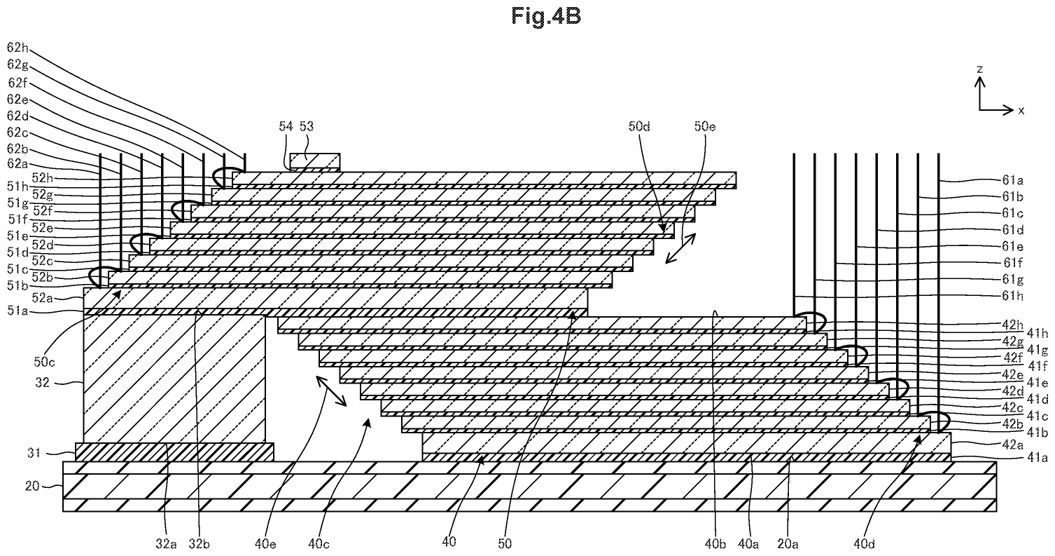

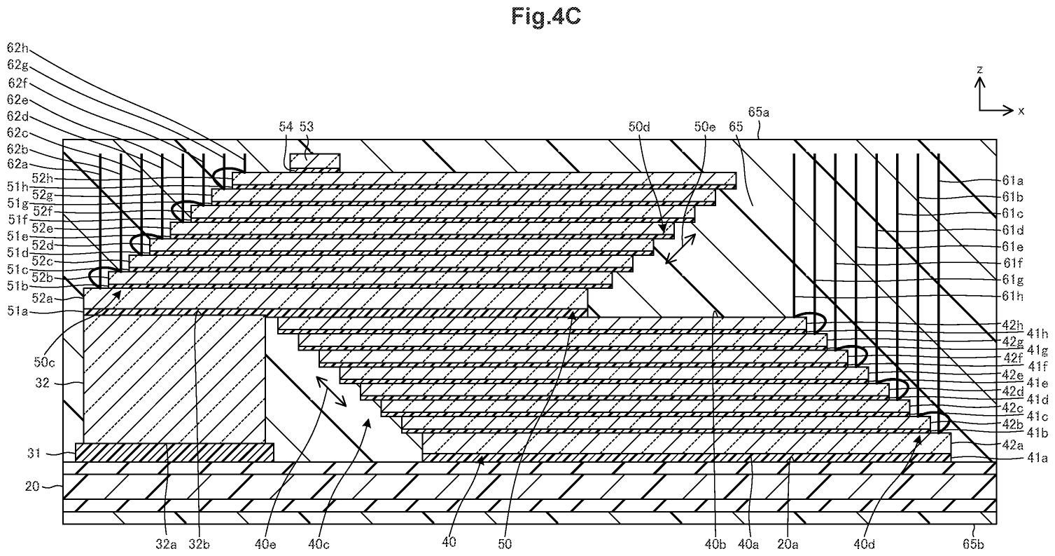

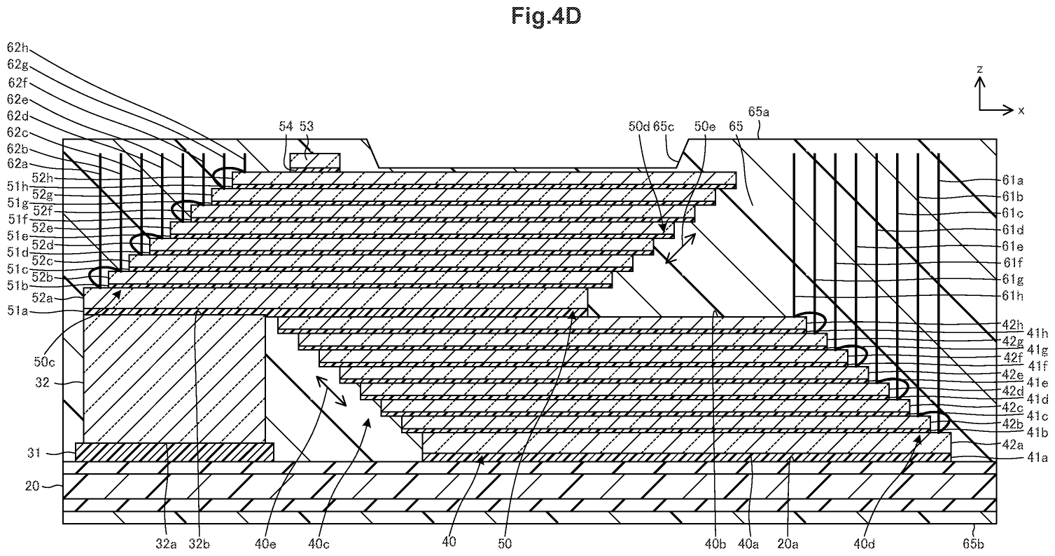

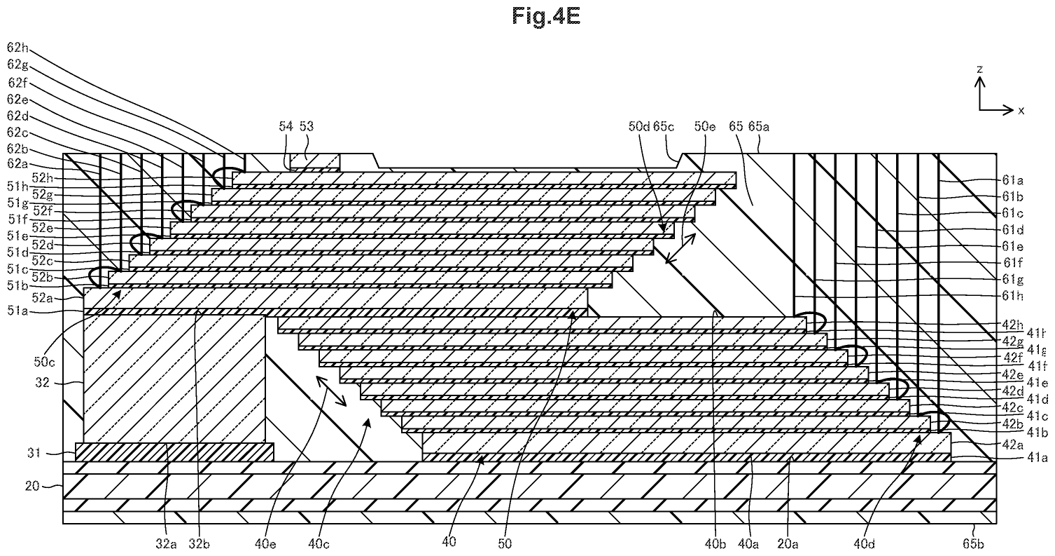

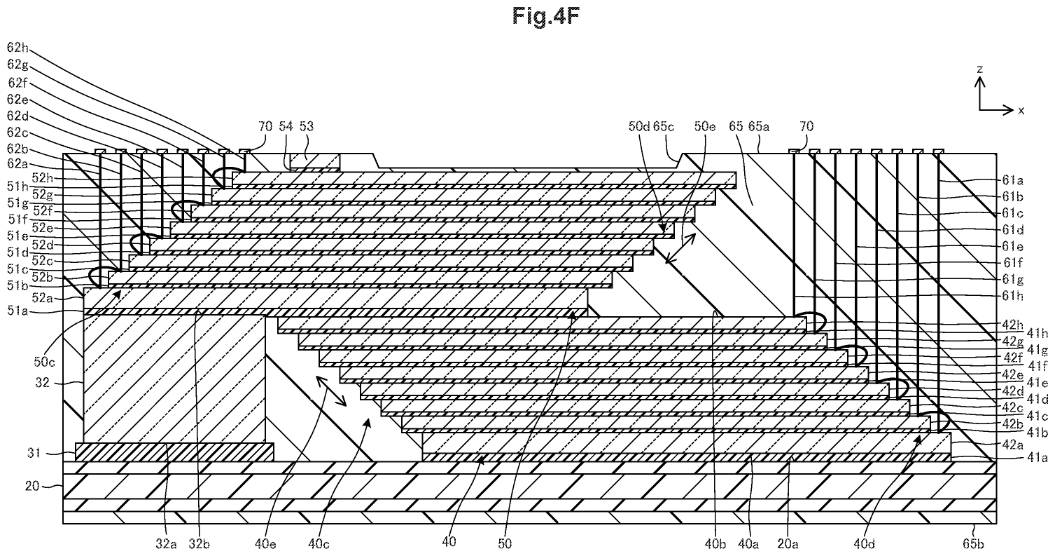

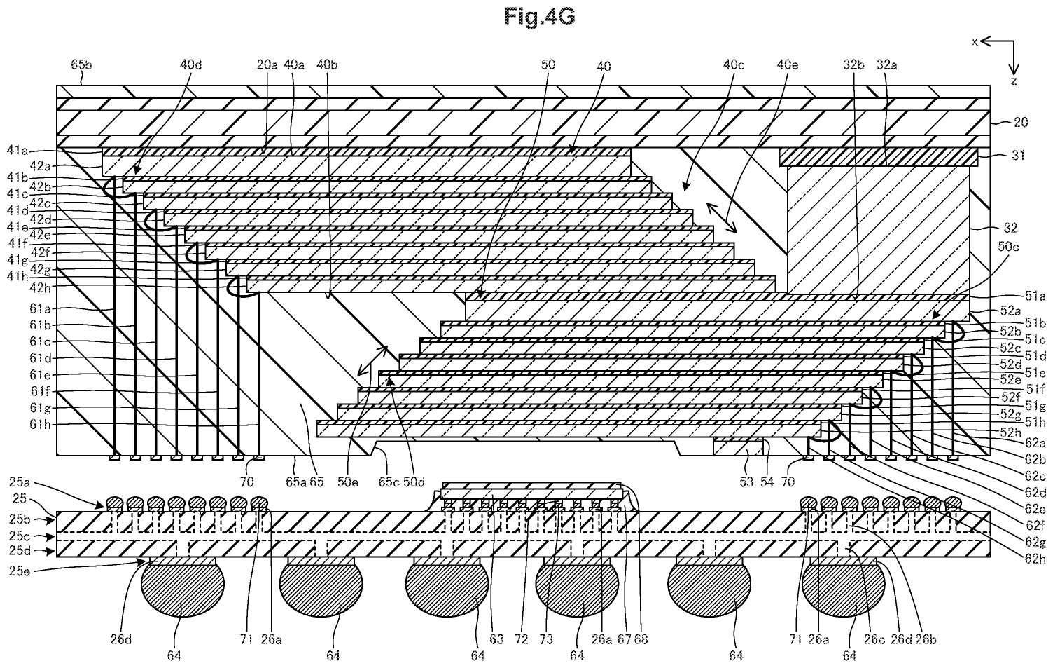

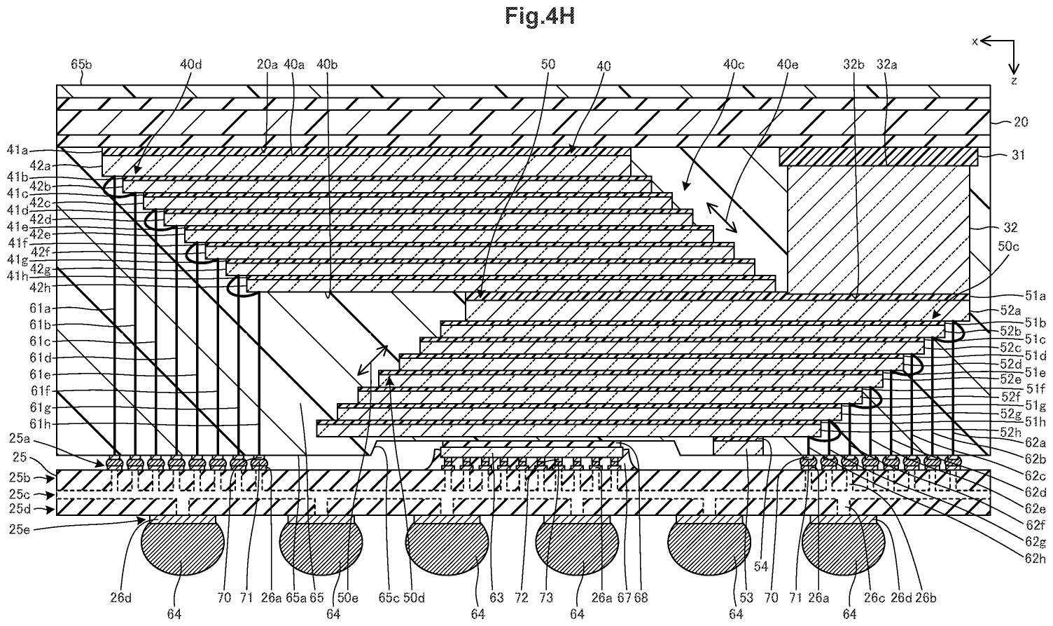

FIGS. 4A to 4H are schematic diagrams illustrating the process of manufacturing the semiconductor device 10. Subsequently, as illustrated in FIG. 4A, the semiconductor chip 52b is disposed on a surface of the semiconductor chip 52a on the controller side with the die attach film 51b interposed therebetween.

Subsequently, similarly, each of the semiconductor chips 52c to 52h on the controller side is fixed to a semiconductor chip 52 on the support substrate side with the corresponding die attach film 51 interposed therebetween.

Subsequently, as illustrated in FIG. 4B, the vertical wires 61a to 61h are formed to extend substantially in parallel to the stacking direction from surfaces of the respective semiconductor chips 42a to 42h toward the controller side, the surfaces being positioned on the controller side and close to end parts on the positive x-axis side.

In addition, the vertical wires 62a to 62h are formed to extend substantially in parallel to the stacking direction from surfaces of the respective semiconductor chips 52a to 52h toward the controller side, the surfaces being positioned on the controller side and close to end parts on the negative x-axis side.

Subsequently, as illustrated in FIG. 4C, the sealing portion 65 is formed to completely cover the support substrate 20, the spacer 32, the die attach films 31, 41, and 51, the semiconductor chips 42 and 52, and the vertical wires 61 and 62.

Subsequently, as illustrated in FIG. 4D, the recessed portion 65c is formed at the surface 65a of the sealing portion 65 on the controller side.

Subsequently, as illustrated in FIG. 4E, the surface 65a of the sealing portion 65 on the controller side is polished. Accordingly, the end parts of the vertical wires 61a to 61h and 62a to 62h on the controller side are exposed. The spacer 53 has largely different characteristics for polishing from those of the sealing portion 65. A physical quantity (such as drive current of a polishing motor) being monitored changes when the spacer 53 is exposed while a polishing amount is monitored. This can be used for end point detection. Thus, the spacer 53 can be used for end point detection of the polishing. The recessed portion 65c may be formed after the sealing portion 65 is polished.

Subsequently, as illustrated in FIG. 4F, seven electrodes 70 positioned on the positive x-axis side and seven electrodes 70 positioned on the negative x-axis side are formed on the surface 65a of the sealing portion 65 on the controller side. The seven electrodes 70 on the positive x-axis side are electrically connected to the end parts of the vertical wires 61a to 61h, respectively, on the controller side. The seven electrodes 70 on the negative x-axis side are electrically connected to the end parts of the vertical wires 62a to 62h, respectively, on the controller side. The electrodes 70 are formed of, for example, Ni/Pd/Au. The material Au is positioned outermost. The electrodes 70 are formed by, for example, plating. Alternatively, the electrodes 70 may be formed by further forming a rewiring layer on the surface 65a.

Subsequently, as illustrated in FIG. 4G, the wiring substrate 25 is prepared. The semiconductor chip 63 is mounted face-down on the wiring substrate 25. The semiconductor chip 63 is sealed by the sealing portion 67. The liquid resin portion 68 is applied on a back surface (surface on the negative z-axis side) of the semiconductor chip 63.

Subsequently, as illustrated in FIG. 4H, the wiring substrate 25 is displaced closer to the chip stacked bodies 40 and 50 so that the seven electrodes 70 on the negative x-axis side are electrically connected to the seven bumps 71 on the negative x-axis side and the seven electrodes 70 on the positive x-axis side are electrically connected to the seven bumps 71 on the positive x-axis side. Thereafter, the liquid resin portion 68 may be cured by further heating.

Subsequently, the semiconductor device 10 is completed (refer to FIG. 1) by filling a gap between the wiring substrate 25 and the chip stacked bodies 40 and 50 with the sealing portion 66.

In the state illustrated in FIG. 4G, the semiconductor chip 63 does not necessarily need to be sealed by the sealing portion 67. In this case, the sealing portion 66 also functions as the sealing portion 67.

Moreover, the resin portion 68 does not necessarily need to be applied to the semiconductor chip 63. In this case, the sealing portion 66 also functions the resin portion 68.

Furthermore, the sealing portion 67 and the resin portion 68 do not necessarily need to be used. In this case, the sealing portion 66 also functions the sealing portion 67 and the resin portion 68.

[Semiconductor Device Manufacturing Method According to Reference Example]

A semiconductor device manufacturing method according to a reference example will be described below.

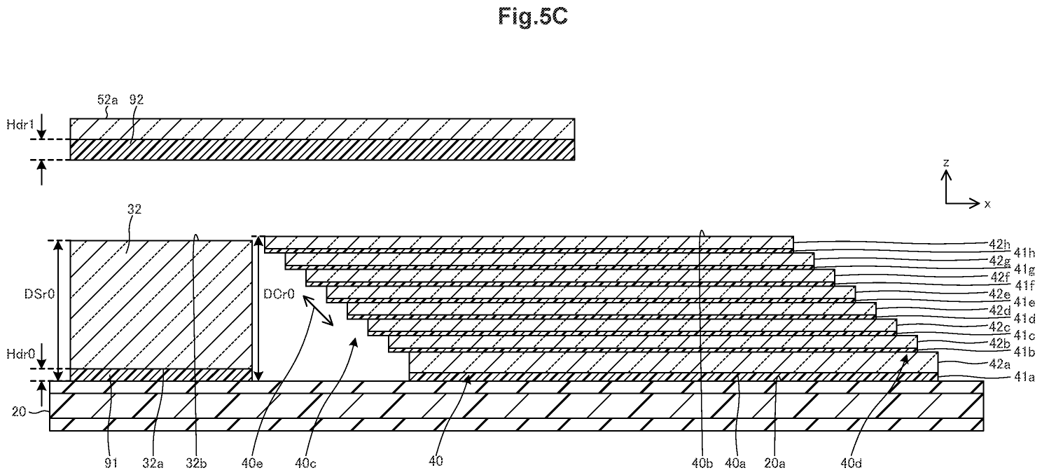

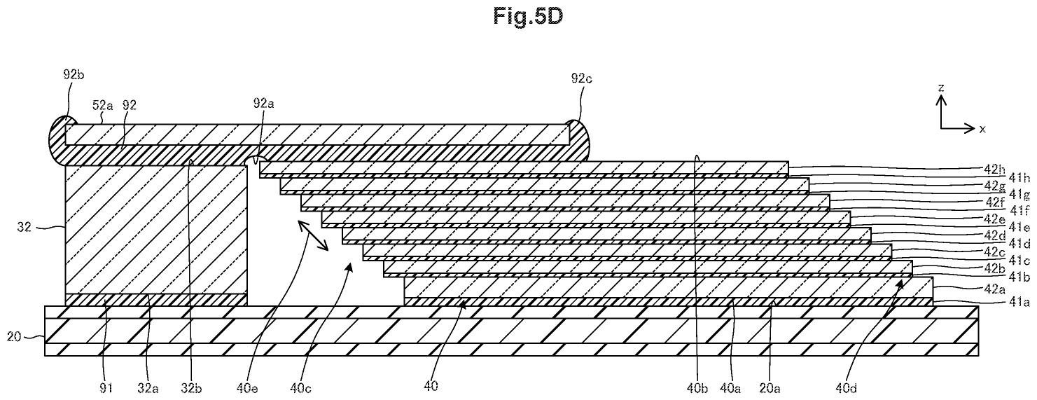

FIGS. 5C and 5D are schematic diagrams illustrating a semiconductor device manufacturing process according to the reference example. In the semiconductor device manufacturing process according to the reference example, die attach films 91 and 92 are used in place of the die attach films 31 and 51a, respectively.

The lowest melt viscosity of the die attach film 92 is low. An initial thickness Hdr1 of the die attach film 92 in the stacking direction is larger than an initial thickness Hdr0 of the die attach film 91 in the stacking direction. The process of manufacturing the semiconductor device 10 illustrated in FIGS. 2A and 2B is performed first.

Subsequently, as illustrated in FIG. 5C, the spacer 32 is disposed at a position on the principal surface 20a with the die attach film 91 interposed therebetween, the position being apart on the negative x-axis side from the chip stacked body 40.

A distance DSr0 between the principal surface 20a and the surface 32b can be equal to or larger than a distance DCr0 between the principal surface 20a and the surface 40b or smaller than the distance DCr0, depending on variance in the thicknesses of the die attach films 41 and 91 in the stacking direction and variance in the thicknesses of the semiconductor chips 42 and the spacer 32 in the stacking direction.

In the semiconductor device manufacturing method according to the reference example, misalignment between the surface 32b and the surface 40b is absorbed as the die attach film 92 more largely deforms than the die attach film 91.

Subsequently, at least the die attach film 92 is heated to a predetermined temperature. The elastic modulus of the die attach film 92 is smaller than the elastic modulus of the die attach film 91 at the predetermined temperature.

Subsequently, as illustrated in FIG. 5D, the die attach film 92 and the semiconductor chip 52a are disposed across the surface 40b of the chip stacked body 40 and the surface 32b of the spacer 32 such that the die attach film 92 is positioned between the semiconductor chip 52a and each of the spacer 32 and the chip stacked body 40.

The semiconductor chip 52a is pressed toward the support substrate side when the die attach film 92 is at the predetermined temperature. The die attach film 92 deforms when pressed toward the support substrate side by the semiconductor chip 52a. The die attach film 92 deforms when pressed toward the support substrate side by the semiconductor chip 52a through the spacer 32 and the die attach film 92. In this state, the surface 32b is displaced toward a surface of the semiconductor chip 52a on the support substrate side.

The amount of deformation of the die attach film 92 is larger than the amount of deformation of the die attach film 91 since the die attach film 92 is softer than the die attach film 91 in this state.

Subsequently, at least the die attach films 91 and 92 are cured by heating so that the semiconductor chip 52a is fixed to the spacer 32 and the chip stacked body 40.

The chip stacked body 40 warps when the die attach films 91 and 92 are cured by heating. Due to such warping of the chip stacked body 40, a sink is generated at the die attach film 92 that is thick and soft, and a hollow space 92a is formed in some cases.

The hollow space 92a is unlikely to be buried by molding resin when sealed by the sealing portion 65, and thus a void is likely to be generated. This is not preferable because vapor explosion occurs at the void when reflow processing is performed.

The die attach film 92 protrudes from end parts on the negative x-axis side and the positive x-axis side as the semiconductor chip 52a is pressed toward the support substrate side. Since the amount of protrusion is large due to the large thickness of the die attach film 92 and the elastic modulus of the die attach film 92 is small, the protruding die attach film 92 climbs onto the surface of the semiconductor chip 52a on the controller side and forms climbing portions 92b and 92c in some cases. This is not preferable because wiring connection is highly likely to be difficult in a case in which pads provided on the surface on the controller side are contaminated by the climbing portions 92b and 92c. Furthermore, flatness of a surface of the die attach film 51a on the controller side is lost because the climbing portions 92b and 92c exist, and thus the semiconductor chip 52b is potentially disposed and fixed at a tilt.

However, in the present application, misalignment between the surface 32b and the surface 40b is absorbed since the die attach film 31 on the support substrate side of the spacer 32 largely deforms as illustrated in FIG. 2D. With such a configuration, the thickness of the die attach film 51a in the stacking direction can be reduced, and thus sink generation at the die attach film 51a can be prevented. Moreover, since no step needs to be buried, a hard material having a large elastic modulus can be used as the die attach film 51a, and thus sink generation can be further prevented.

When pressed by the spacer 32, the die attach film 31 becomes thin and circumferentially protrudes, thereby preventing sink generation in curing by heating. Accordingly, void generation can be prevented, and thus a favorable package can be achieved.

Moreover, since the amount of deformation of the die attach film 51a can be reduced, the die attach film 51a can be prevented from climbing onto the surface of the semiconductor chip 52a on the controller side. Accordingly, the probability of contamination of the pads provided on the surface can be lowered. In addition, since flatness of the surface of the semiconductor chip 52a on the controller side can be excellently maintained, the semiconductor chip 52b can be prevented from being fixed at a tilt.

Furthermore, since the thickness of the die attach film 31 having a size smaller than the size of the die attach film 51a is large, the use amount of the material of die attach films can be reduced, and thus manufacturing cost of the semiconductor device 10 can be reduced.
(a) In the configuration described in the present embodiment, the semiconductor device 10 includes the support substrate 20, but the present invention is not limited to the configuration. Part or all of the support substrate 20 may be removed after the semiconductor device 10 is completed.
(b) In the configuration described in the present embodiment, the stair portions 40c and 40d are formed in the chip stacked body 40, but the present invention is not limited to the configuration. The chip stacked body 40 may be formed to have end parts at which no stair portions 40c and 40d are formed and end faces of the semiconductor chips 42 are aligned. Similarly, the chip stacked body 50 may be formed to have end parts at which no stair portions 50c and 50d are formed and end faces of the semiconductor chips 52 are aligned.
(c) In the configuration described in the present embodiment, the eight semiconductor chips 42 are stacked in the chip stacked body 40, but the present invention is not limited to the configuration. Two to seven semiconductor chips 42 or nine or more semiconductor chips 42 may be stacked in the chip stacked body 40. Similarly, two to seven semiconductor chips 52 or nine or more semiconductor chips 52 may be stacked in the chip stacked body 50.
(d) In the configuration described in the present embodiment, the vertical wires 61 are connected to the semiconductor chips 42 in the chip stacked body 40, but the present invention is not limited to the configuration. Wires may be connected to the semiconductor chips 42 by another connection method such as wire bonding. Similarly, instead of the vertical wires 62 to the semiconductor chips 52 in the chip stacked body 50, wires may be connected to the semiconductor chip 52 by another connection method such as wire bonding.
(e)

A semiconductor device according to the present disclosure includes
a first chip stacked body including a plurality of first semiconductor chips stacked in a stacking direction, the first chip stacked body having a first surface and a second surface on a first side and a second side corresponding to respective ends in the stacking direction;
a spacer extending in the stacking direction and positioned with respect to the first chip stacked body in a direction intersecting the stacking direction, the spacer having a third surface and a fourth surface at the respective ends on the first side and the second side in the stacking direction; and
a second semiconductor chip and a first resin layer provided across the second surface of the first chip stacked body and the fourth surface of the spacer, the first resin layer being positioned between the second semiconductor chip and each of the spacer and the first chip stacked body,
in which an interval between the first surface and the third surface in the stacking direction is larger than an interval between the second surface and the fourth surface in the stacking direction.

The present embodiment is described above with reference to specific examples. However, the present disclosure is not limited to these specific examples. Those obtained by changing designing of the specific examples as appropriate by the skilled person in the art are included in the scope of the present disclosure as long as they have features of the present disclosure. Each element included in each above-described specific example and, for example, the disposition, condition, and shape thereof are not limited to those exemplarily shown but may be changed as appropriate. Combination of elements included in the above-described specific examples may be changed as appropriate without technological inconsistency.

What is claimed is:

1. A semiconductor device comprising:
a first chip stacked body including a plurality of first semiconductor chips stacked in a stacking direction, the first chip stacked body having a first surface and a second surface at respective ends on a first side and a second side in the stacking direction;
a spacer extending in the stacking direction and positioned with respect to the first chip stacked body in a direction intersecting the stacking direction, the spacer having a third surface and a fourth surface at the respective ends on the first side and the second side in the stacking direction;
a second semiconductor chip and a first resin layer provided across the second surface of the first chip stacked body and the fourth surface of the spacer, the first resin layer being positioned between the second semiconductor chip and each of the spacer and the first chip stacked body; and
a second resin layer provided on the third surface of the spacer and having a thickness larger than a thickness of the first resin layer.

2. The semiconductor device according to claim 1, wherein an interval between the first surface and the third surface in the stacking direction is larger than an interval between the second surface and the fourth surface in the stacking direction.

3. The semiconductor device according to claim 1, wherein
the first resin layer and the second resin layer are made of heat-curable resin, and
an elastic modulus of the second resin layer is smaller than an elastic modulus of the first resin layer at a temperature before curing.

4. The semiconductor device according to claim 1, wherein in the first chip stacked body, the plurality of first semiconductor chips are stacked such that a first stair portion is formed at a side surface facing the spacer, the first stair portion having a stair shape in which the first stair portion is further apart from the spacer at a position further apart from the second semiconductor chip.

5. The semiconductor device according to claim 1, wherein in the first chip stacked body, the plurality of first semiconductor chips are stacked such that a second stair portion is formed at a side surface on a side further apart from the spacer, the second stair portion having a stair shape in which the second stair portion is further apart from the spacer at a position further apart from the second semiconductor chip.

6. The semiconductor device according to claim 5, wherein the second semiconductor chip and the first resin layer are apart from the second stair portion in a plan view in which the second surface is viewed in the stacking direction.

7. The semiconductor device according to claim 5, further comprising a wire extending toward the second side from a surface of the second stair portion on the second side.

8. The semiconductor device according to claim 1, further comprising a second chip stacked body including the second semiconductor chip and a plurality of third semiconductor chips stacked in the stacking direction on the second side of the second semiconductor chip.

9. The semiconductor device according to claim 8, wherein
in the first chip stacked body, the plurality of first semiconductor chips are stacked such that a first stair portion is formed at a side surface facing the spacer, the first stair portion having a stair shape in which the first stair portion is further apart from the spacer at a position further apart from the second semiconductor chip, and
in the second chip stacked body, the second semiconductor chip and the plurality of third semiconductor chips are stacked such that a third stair portion is formed, the third stair portion having a stair shape having a second stair up-down direction intersecting a first stair up-down direction of the first stair portion.

10. The semiconductor device according to claim 1, further comprising:
a third resin layer provided on the first surface of the first chip stacked body; and
a support substrate provided across a surface of the second resin layer on the first side and a surface of the third resin layer on the first side.

11. A semiconductor device manufacturing method comprising:
forming a first chip stacked body and a third resin layer on a principal surface of a support substrate, the first chip stacked body including a plurality of first semiconductor chips stacked in a stacking direction, the first chip stacked body having a first surface and a second surface at respective ends on a first side and a second side in the stacking direction, the third resin layer being provided between the first surface of the first chip stacked body and the principal surface;
disposing a spacer at a position on the principal surface with a second resin layer interposed between the spacer and the principal surface, the spacer extending in the stacking direction and having a third surface and a fourth surface at the respective ends on the first side and the second side in the stacking direction, the position being apart from the first chip stacked body in a direction intersecting the stacking direction, the second resin layer having a thickness with which a distance between the principal surface and the fourth surface is larger than a distance between the principal surface and the second surface;
disposing a first resin layer and a second semiconductor chip across the second surface of the first chip stacked body and the fourth surface of the spacer such that the first resin layer is positioned between the second semiconductor chip and each of the spacer and the first chip stacked body; and
curing at least the first resin layer and the second resin layer by heating.

12. The semiconductor device manufacturing method according to claim 11, wherein in the disposing of the first resin layer and the second semiconductor chip, the third surface of the spacer is displaced toward the principal surface.

13. The semiconductor device manufacturing method according to claim 12, wherein an elastic modulus of the second resin layer when the third surface of the spacer is displaced closer to the principal surface is smaller than an elastic modulus of the first resin layer.

14. The semiconductor device manufacturing method according to claim 11, wherein an elastic modulus of the second resin layer is smaller than an elastic modulus of the first resin layer before the curing.

15. The semiconductor device manufacturing method according to claim 11, wherein a thickness of the second resin layer is larger than a sum of an upper limit value of tolerance of the first chip stacked body, an upper limit value of tolerance of the third resin layer, a lower limit value of tolerance of the spacer, and a lower limit value of tolerance of the second resin layer.
